(19) United States
(12) Patent Application Publication
(10) Pub. No.: US 2019/0043982 A1
(43) Pub. Date: Feb. 7, 2019

(54) Transistor Device with Trench Edge Termination

(71) Applicant: Infineon Technologies AG, Neubiberg (DE)

(72) Inventors: Adrian Finney, Villach (AT); Marius Aurel Bodea, Villach (AT)

(21) Appl. No.: 16/050,950

(22) Filed: Jul. 31, 2018

(30) Foreign Application Priority Data
Aug. 1, 2017 (DE) 102017117442.7

(51) Int. Cl. H01L 29/78; H01L 29/66; H01L 29/08; H01L 29/10; H01L 29/40

(52) U.S. Cl. CPC H01L 29/7811; H01L 29/7813; H01L 29/66734; H01L 29/407; H01L 29/0873; H01L 29/1095; H01L 29/0856

(57) ABSTRACT

Disclosed are a transistor device and a method. The transistor device includes a semiconductor body with a first surface, an inner region, and an edge region, a drift region of a first doping type in the inner region and the edge region, a plurality of transistor cells in the inner region, and a termination structure in the edge region. The termination structure includes a recess extending from the first surface in the edge region into the semiconductor body, and a floating compensation region with dopant atoms of a second doping type complementary to the first doping type in the drift region adjacent the recess.

### TECHNICAL FIELD

This disclosure in general relates to a semiconductor device, in particular a power semiconductor device, with a vertical edge termination.

### BACKGROUND

Power semiconductor devices, such as power diodes, power MOSFETs, power IGBTs or power thyristors, are designed to withstand high blocking voltages. Those power devices include a pn-junction formed between a p-doped semiconductor region and an n-doped semiconductor region. The device blocks (is switched off) when the pn-junction is reverse biased by applying a voltage to the pn-junction. In this case a depletion region or space charge region expands in the p-doped region and the n-doped region. Usually one of these p-doped and n-doped regions is more lightly doped than the other one of these p-doped and n-doped regions, so that the depletion region mainly expands in the more lightly doped region, which mainly supports the voltage applied across the pn-junction. The more lightly doped region supporting the blocking voltage is usually referred to as drift region in a MOSFET or IGBT or as a base region in a diode or thyristor.

The ability of a pn-junction to support high voltages is limited by the avalanche breakdown phenomenon. As a voltage applied across a pn-junction increases, an electric field in the semiconductor regions forming the pn-junction increases. The electric field results in acceleration of mobile carriers induced by thermal generation in the space charge region. An avalanche breakdown occurs when, due to the electric field, the charge carriers are accelerated such that they create electron-hole pairs by impact ionization. Charge carriers created by impact ionization create new charge carriers, so that there is a multiplication effect. At the onset of avalanche breakdown a significant current flows across the pn-junction in the reverse direction. The electric field at which the avalanche breakdown sets in is referred to as critical electric field. The absolute value of the critical electric field is mainly dependent on the type of semiconductor material used for forming the pn-junction, and is weakly dependent on the doping concentration of the more lightly doped semiconductor region. A voltage blocking capability of the semiconductor device is the voltage applied to the pn-junction at which the critical electric field occurs in the semiconductor device. This voltage is often referred to as breakdown voltage.

The voltage blocking capability is not only dependent on the type of semiconductor material and its doping, but also on the specific geometry of the semiconductor device. A power semiconductor device includes a semiconductor body of finite size that is terminated by edge surfaces in lateral directions of the semiconductor body. In a vertical power semiconductor device, which is a semiconductor device in which the pn-junction mainly extends in a horizontal plane of the semiconductor body, the pn-junction usually does not extend to the edge surface of the semiconductor body. Instead, the pn-junction is distant to the edge surface of the semiconductor body in a lateral direction. In this case, a semiconductor region (edge region) of the semiconductor body adjoining the pn junction in the lateral direction also has to withstand the voltage applied to the pn-junction.

The edge region could be implemented with a planar edge termination structure. In this case, however, the dimension of the edge region in the lateral direction of the semiconductor body is usually a least between two times and three times the dimension (length) of the drift region (base region) in the vertical direction. The length of the drift region (base region) is dependent on the desired voltage blocking capability of the device and can be up to several 10 micrometers (μm), so that a corresponding edge termination would be very space consuming.

In order to reduce the space required for withstanding the blocking voltage in the edge region, a vertical edge termination, which is sometimes also referred to as mesa edge termination, can be provided. Such vertical edge termination includes a trench in an edge region of the semiconductor body.

There is a need for an improved edge termination for semiconductor devices, in particular semiconductor devices having a semiconductor body with a rectangular geometry.

### SUMMARY

One example relates to a transistor device. The transistor device includes a semiconductor body with a first surface, an inner region, and an edge region, a drift region of a first doping type in the inner region and the edge region. a plurality of transistor cells in the inner region, and a termination structure in the edge region. The termination structure includes a recess extending from the first surface in the edge region into the semiconductor body, at least one floating compensation region with dopant atoms of a second doping type complementary to the first doping type in the drift region adjacent the recess.

Another example relates to a method. The method includes forming a drift of a first doping type in an inner region and an edge region of a semiconductor, forming a plurality of transistor cells in the inner region, and forming a termination structure in the edge region. Forming the termination structure includes forming a recess extending, in the edge region, from the first surface in the edge region into the semiconductor body, forming at least one floating compensation region comprising dopant atoms of a second doping type complementary to the first doping type in the drift region adjacent the recess, and, in the recess, forming a field electrode dielectrically insulated from the semiconductor body by a field electrode dielectric.

Those skilled in the art will recognize additional features and advantages upon reading the following detailed description, and upon viewing the accompanying drawings.

### BRIEF DESCRIPTION OF THE FIGURES

Examples are explained below with reference to the drawings. The drawings serve to illustrate certain principles, so that only aspects necessary for understanding these principles are illustrated. The drawings are not to scale. In the drawings the same reference characters denote like features.

FIG. 1 shows a vertical cross sectional view of a transistor device with a plurality of transistor cells in an inner region of a semiconductor body and a termination structure in an edge region of the semiconductor body;

FIG. 2 shows a modification of the transistor device shown in FIG. 1;

FIG. 3 shows another modification of the transistor device shown in FIG. 1;

FIG. 4 shows a horizontal cross sectional view of the transistor device according to one example;

FIG. 5 shows a horizontal cross sectional view of the transistor device according to another example;

FIGS. 6A and 6B illustrate doping profiles;

FIG. 7 shows a horizontal cross sectional view of the transistor device according to yet another example;

FIG. 8 shows a vertical cross sectional view of a transistor cell according to one example in greater detail;

FIG. 9 shows a vertical cross sectional view of a transistor cell according to another example in greater detail;

FIGS. 10A and 10B show horizontal cross sectional views of the plurality of transistor cells according to different examples;

FIG. 11 shows one section of the termination structure according to another example; and

FIGS. 12A to 12C illustrate one example of a method for forming a floating compensation region of the trench termination structure.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

FIG. 1 illustrates a vertical cross sectional view of a transistor device according to one example. The transistor device includes a semiconductor body 100 with a first surface 101, an inner region 104, and an edge region 105. The edge region 105 adjoins the inner region 104 in a lateral direction of the semiconductor body 100, wherein the lateral direction is a direction parallel to the first surface 101.

According to one example, the edge region 105 surrounds the inner region 104 in lateral directions of the semiconductor body. This is illustrated in FIGS. 4 and 5, each of which shows a horizontal cross sectional view of the semiconductor body 100. According to one example shown in FIG. 4, the edge region 105 adjoins an edge surface 103 of the semiconductor body 100, wherein the edge surface terminates the semiconductor body 100 in lateral directions. According to one example shown in FIG. 5, the edge region 105 surrounds the inner region 104 but does not adjoin the edge surface 103. In this example, further semiconductor devices may be integrated in the semiconductor body 100 between the edge region 105 and the edge surface 103. In each case, however, the edge region 105 forms the edge of the transistor device integrated in the semiconductor body 100.

Referring to FIG. 1, the transistor device includes a drift region 11 of a first doping type in the inner region 104 and the edge region 105, a plurality of transistor cells 10 in the inner region 104, and a termination structure in the edge region 105. Each of the transistor cells 10 includes a source region 13, a body region 12 arranged between the source region 13 and the drift region 11, and a gate electrode 21. The gate electrode 21 is adjacent the body region 12 and dielectrically insulated from the body region 12 by a gate dielectric 22. Just for the purpose of illustration, the gate electrodes 21 of the individual transistor cells are arranged in trenches extending from the first surface 101 into the semiconductor body 100. According to another example (not shown) the gate electrodes 21 are planar electrodes arranged on top of the first surface 101 of the semiconductor body 100. The gate electrodes 21 are electrically connected to a gate node G, wherein electrical connections between the gate electrodes 21 and the gate node G are only schematically illustrated in FIG. 1. Further, the source regions 13 and the body regions 12 of the individual transistor cells are electrically connected to a source node S, wherein connections between the source regions 13 and the body regions 12 and the source node S are only schematically illustrated in FIG. 1.

Referring to FIG. 1, the transistor device further includes a drain region 14. The drain region 14 is spaced apart from the body regions 12 in a vertical direction of the semiconductor body 100. The “vertical direction” is a direction perpendicular to the first surface 101. The drain region 14 may adjoin a second surface 102 opposite the first surface 101 of the semiconductor body 100. The drift region 11 is arranged between the body regions 12 of the individual transistor cells 10 and the drain region 14. According to one example, the drain region 14 adjoins the drift region 11. According to another example, a field-stop region 15 of the same doping type as the drift region 11, but more highly doped than the drift region 11 is arranged between the drift region 11 and the drain region 14. Such field-stop region 15 is illustrated in dashed lines in FIG. 1.

The transistor device can be implemented as an n-type transistor device or a p-type transistor device. In an n-type transistor device, the drift region 11 and the source regions 13 are n-doped, while the body regions 12 are p-doped. In a p-type transistor device, the doping types of the individual device regions are complementary to the doping types of the device regions in an n-type transistor device. The transistor device may be implemented as an enhancement (normally-off) device or as a depletion (normally-on) device. In an enhancement device, the body region 12, which has a doping type complementary to the doping type of the source regions 13 and the drift region 11, adjoins the gate dielectric 22. In a depletion device, there is a channel region of the same doping type as the drift region 11 and the source region 13 along the gate dielectric 22 between the source region 13 and the drift region 11. In any case, the gate electrode 21 serves to control a conducting channel around the gate dielectric 22 between the source region 13 and the drift region 11. The transistor device is in an on-state when there is a conducting channel along the gate dielectric 22, and in an off-state when there is no such conducting channel. An enhancement device is in the on-state when the gate electrode 21 is drive such that there is an inversion channel in the body region 12 along the gate dielectric 22 and in an off-state when the inversion channel is interrupted. A depletion device is in the off-state when the gate electrode 21 is driven such that the channel region along the gate dielectric 21 is depleted, and a depletion device is in the on-state when the channel region is not depleted.

Further, the transistor device can be implemented as a MOSFET or an IGBT. In a MOSFET, the drain region 14 has the same doping type as the drift region 11, and in an IGBT, the drain region 14 (which may also be referred to as collector region) has a doping type complementary to the doping type of the drift region 11.

A doping concentration of the drain region 14 is, for example, between 1E19 cm⁻³ and 1E22 cm⁻³, a doping concentration of the drift region 11 is, for example, between 1E13 cm⁻³ and 1E17 cm⁻³, in particular between 1E14 cm⁻³ and 1E16 cm⁻³, a doping concentration of the body region 12 is, for example, between 1E15 cm⁻³ und 1E18 cm⁻³, and the doping concentration of the source region 13 is, for example, between 1E19 cm⁻³ und 1E21 cm⁻³.

Referring to FIG. 1, the termination structure arranged in the edge region 105 of the semiconductor body 100 includes a recess 106 that extends from the first surface 101 into the semiconductor body 100. This recess, in a lateral direction of the semiconductor body 100 may extend to the edge surface 103. The latter, in particular, applies when the edge region 105 adjoins the edge surface 103 as shown in FIG. 4. That is, in an example, in which the edge region 105 adjoins the edge surface 103, the recess 106 may extend to the edge surface 103. Further, in a horizontal plane of the semiconductor body 100, the recess 106 can be ring-shaped and surround the cell region of the transistor device. The “cell region” is the region that includes the plurality of transistor cells.

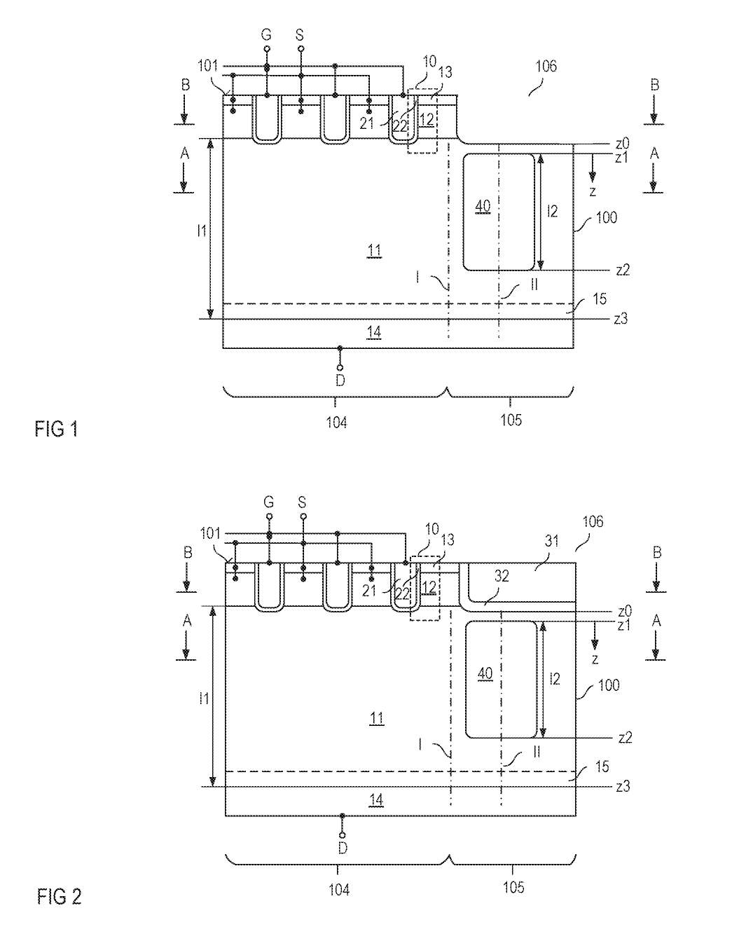

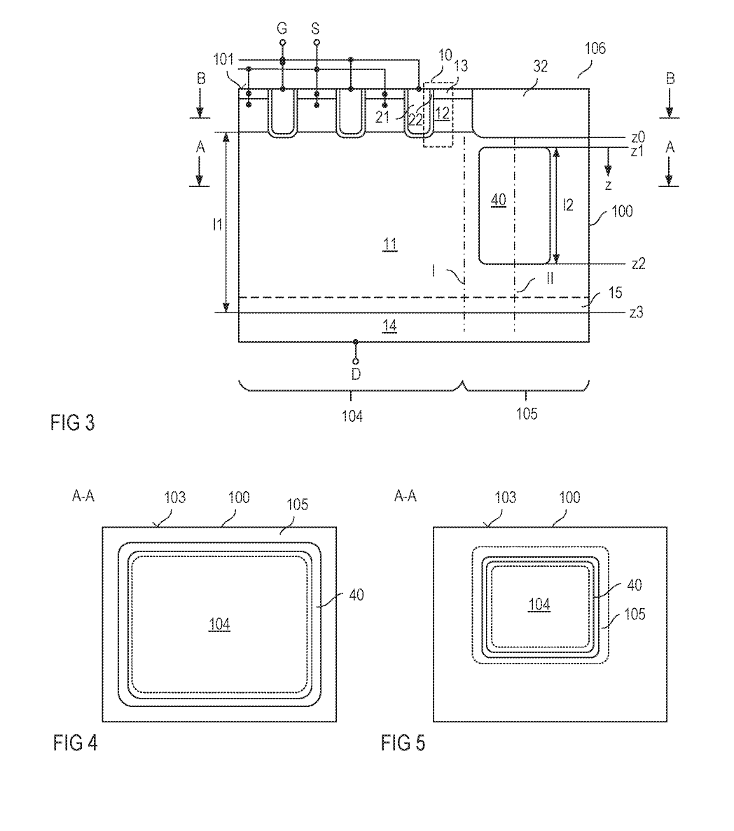

According to one example shown in FIG. 2, a field electrode 31 dielectrically insulated from the semiconductor body 100 by a field electrode dielectric 32 is arranged in the recess. According to one example, the field electrode 31 is electrically connected to the source node. According to another example, the field electrode 31 is electrically connected to gate node G. According to yet another example, the field electrode 31 is floating, that is, not connected to any one of the gate node G, the source node S and the drain node D. According to another example shown in FIG. 3, the field electrode 31 is omitted and the recess is at least partially filled with the dielectric 32. In the example shown in FIG. 3 the recess 106 is completely filled with the dielectric 32. This, however, is only an example. According to another example (not shown) the dielectric covers the semiconductor body 100 in the recess but does not completely fill the recess 106.

In each case, referring to FIGS. 1 to 3, the termination structure further includes a floating compensation region 40 of a second doping type complementary to the first doping type. The floating compensation region 40 is arranged in the drift region 11 in the edge region 105. In the vertical direction of the semiconductor body 100, the floating compensation region 40 is arranged below the recess 106, as seen from the first surface 101.

According to one example (as shown in FIGS. 1 to 3), the floating compensation region 40 is spaced apart from a bottom of the recess 106 in the vertical direction of the semiconductor body 100, so that in the examples shown in FIGS. 2 and 3 the floating compensation region 40 is spaced apart from the (field electrode) dielectric 32. According to another example (not shown) the floating compensation region 40 adjoins the bottom of the recess 106, so that in the examples shown in FIGS. 2 and 3 the floating compensation region 40 adjoins the (field electrode) dielectric 32. The floating compensation region 40, however, is spaced apart from the body regions 12 of the individual transistor cells and is not connected to these body regions 12 via a semiconductor region of the second doping type, so that the compensation region 40 is not electrically connected to the source node S. Further, the floating compensation region 40 is neither electrically connected to the gate node G nor the drain node D.

The drift region 11 has a first length 11 in the vertical direction of the semiconductor body 100. The first length 11 is the distance between the body regions 12 and the drain region 14 or between the body regions 12 and the field stop region 15, if there is a field stop region 15. The floating compensation region 40 has a second the length 12 in the vertical direction of the semiconductor body 100. According to one example, a length ratio 12/11 between the second length 12 and the first length 11 is between 0.4 and 1, in particular between 0.5 and 0.9.

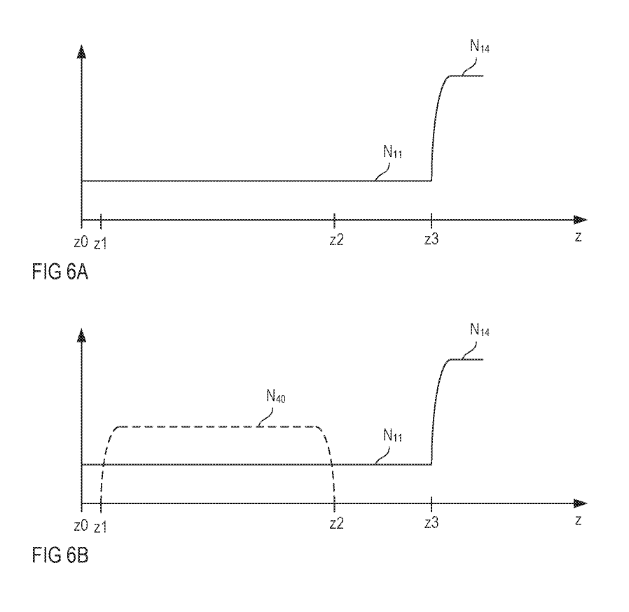

The floating compensation region 40 includes dopants (doping atoms) of a second doping type complementary to a doping type of the drift region 11. If, for example, the transistor device is an n-type transistor device, the dopants of the second doping type are p-type dopants. For example, p-type dopants are aluminum (Al) atoms or boron (B) atoms. Additionally to these second type dopants, the floating compensation region 40 may include first type dopants. In an n-type transistor device, for example, the first type dopants are n-type dopants. For example, n-type dopants are phosphorous (P) atoms. According to one example, a doping profile of the first type dopants in the floating compensation region 40 corresponds to a doping profile of the first type dopants in adjoining regions of the drift region 11. This is illustrated in FIGS. 6A and 6B. FIG. 6A shows the doping profile of the drift region 11 and the drain region 14 (just for the purpose of illustration it is assumed that there is no field stop region 15) along a line I that extends in the vertical direction z of the semiconductor body 100 beginning at vertical position z0. The vertical position z0 is the position of an interface between the field electrode dielectric 32 and the drift region 11. Line I is adjacent the floating compensation region 40. In FIG. 6A, N₁₁ denotes the doping concentration of the drift region 11 along a line I and, therefore, shows the doping profile of the drift region 11 along line I. Just for the purpose of illustration, in the example shown in FIG. 6A, the drift region 11 has an essentially homogenous doping profile, that is, the doping concentration N₁₁ is essentially constant. According to another example, (not shown) the doping concentration N₁₁ of the drift region 11 may increase or decrease towards the drain region 14.

FIG. 6B shows the doping profile along a line 11 that extends in the vertical direction z and goes through the floating compensation region 40. In FIG. 6B, N₁₁ denotes the doping concentration or doping profile of first type dopant atoms that result from the doping of the drift region 11. Additionally, to these first type dopants, the floating compensation region 40 includes second type dopants. The doping concentration or doping profile of these second type dopants is labeled with N₄₀ in FIG. 6B and illustrated in dashed lines. Just for the purpose of illustration, the doping concentration of the second type dopants in the compensation region 40 is drawn to be essentially constant in the example shown in FIG. 6B. The effective doping concentration of the compensation region 40 is dependent on which of the first type dopants and the second type dopants prevail in the compensation region 40. That is, the compensation region 40 is, effectively, a region of the second doping type if the second type doping concentration N₄₀ is higher than the first type doping concentration N₁₁, and the compensation region, effectively, is a region of the first doping type if the second type doping concentration N₄₀ is lower than the first type doping concentration N₁₁.

The drift region 11 has a doping dose D₁₁, wherein the doping dose D₁₁ is the integral of the doping concentration N₁₁ along a line in the vertical direction z between the vertical positions z0 and z3, that is, between the field electrode dielectric 32 and the drain region 14. That is, the doping dose D₁₁ is given by

$${D}_{11} = {\int }_{z 0}^{z 3} {N}_{11} ( z ) dz . \qquad ( 1 )$$

A doping dose of the second type dopant atoms in the compensation region 40 is given by the integral in the vertical direction z between the positions z1 and z2, wherein these positions z1 and z2 are the vertical positions of interfaces between the compensation region 40 and the drift region 11. That is, these positions define an upper end and a lower end of the compensation region 40. Thus, the second type doping dose D40 is given by

$${D}_{40} = {\int }_{z 1}^{z 2} {N}_{40} ( z ) dz . \qquad ( 2 )$$

In the following, D₁₁ is referred to as first doping dose, and D₄₀ is referred to as second doping dose. Further, a ratio D₄₀/D₁₁ between the second doping dose D₄₀ and the first doping dose D₁₁ is referred to as dose ratio. According to one example, the drift region 11 and the floating compensation region 40 are formed such that the dose ratio D₄₀/D₁₁ is between 0.5 and 4, in particular between 0.7 and 2.5. According to one example, the second doping dose D40 is selected from between 1E11 cm⁻³ and 1E13 cm⁻³. Referring to the above, the compensation region 40 may include first type dopants. If, for example, a doping profile of the first type dopants in the compensation region 40 equals a doping profile of the first type dopants in the drift region, a doping dose of first type dopants in the compensation region is given by

$${D}_{11}^{′} = {\int }_{z 1}^{z 2} {N}_{11} ( z ) dz , \qquad ( 3 )$$

which is the integral of the first type doping concentration N₁₁ between the upper end (position z1) and the lower end (position z2) of the compensation region 40.

Dependent on the dose ratio D₄₀/D₁₁, the compensation region 40 may have an effective doping concentration of the second type or an effective doping concentration of the first doping type. The compensation region has an effective doping concentration of the second type when the overall number of second type dopants in the compensation region 40 outnumbers the overall number of first type dopants in the compensation region 40 and an effective doping concentration of the first type when the overall number of first type dopants in the compensation region 40 outnumbers the overall number of second type dopants in the compensation region 40. In each case, the compensation region 40 is that region in the drift region that includes the second type dopants. The overall number of second type dopant atoms in the compensation region 40 is given by the second doping dose D₄₀, and the overall number of first type dopant atoms in the compensation region 40 is given by D₁₁′ according to equation (3).

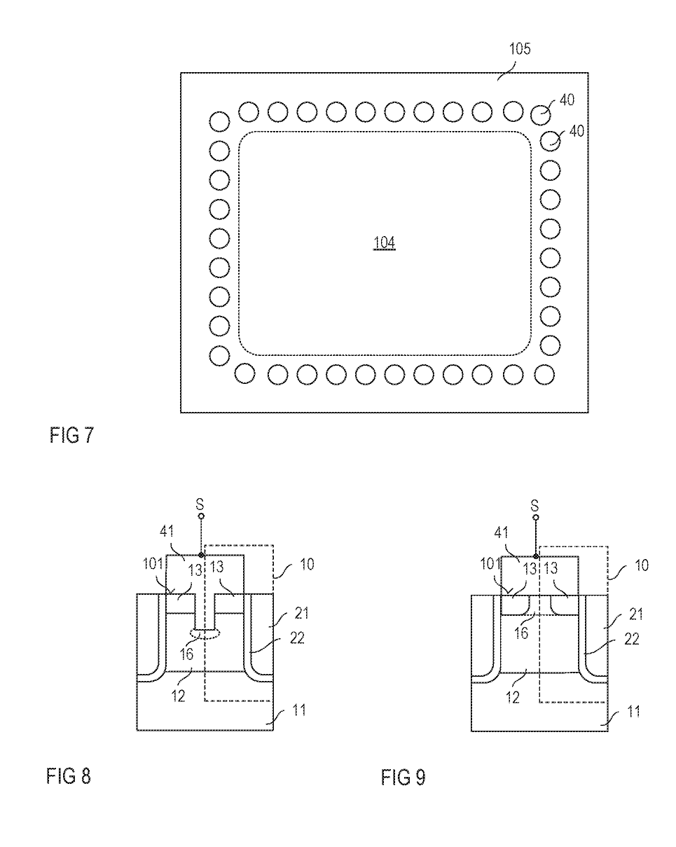

The transistor device includes at least one floating compensation region 40 of the type explained herein before. According to one example, as schematically illustrated in FIGS. 2 and 3, the transistor device includes only one floating compensation region 40, wherein this floating compensation region 40, in a horizontal section plane of the semiconductor body 100, is ring-shaped and surrounds the drift region 11 in the inner regions 104. According to another example shown in FIG. 7, the transistor device includes a plurality of floating compensation regions 40 wherein the plurality of these floating compensation regions 40 form a ring around the drift region 11 in the inner region 104.

The transistor device with the plurality of transistor cells and the termination structure with the at least one floating compensation region 40 can be operated like a conventional transistor device. When the transistor device is in the on-state and the voltage is applied between the drain node D and the source node S, a current can flow between the drain node D and the source node S. When the transistor device is in the off-state, and a voltage is applied between the drain node D and the source node S such that a pn junction between the drift region 11 and the body regions 12 is reverse biased a space charge region (depletion region) expands in the drift region 11, wherein this depletion region expands in the direction of the drain region 14 as the voltage that reverse biases the pn junction increases. This depletion region is associated with an electric field, wherein an avalanche breakdown occurs when the field strength of the electric field regions reaches a critical level (which is often referred to as critical electric field). The depletion region expanding in the drift region 11 is associated with the ionization of dopant atoms in the drift region 11 and the ionization of dopant atoms in the body region 12. The ionized dopant atoms have a positive charge when the respective semiconductor region is n-doped and have a negative charge when the respective semiconductor region is p-doped. That is, there are positive dopant charges in the drift region 11 and negative dopant charges in the body region 11 if the drift region 11 is n-doped and the body region 12 is p-doped.

Each ionized dopant atom in the drift region 11 has a counter charge of an opposite type. In the transistor device according to one of FIGS. 1 to 3, this counter charge, in the inner region 104, is provided by ionized dopant atom in the body region 12. In the edge region 105, when the depletion region reaches the compensation region 40, the second type dopants in the compensation region 40 are ionized and provide a counter charge to ionized dopant atoms in the drift region 11. By virtue of the floating compensation region 40, the voltage blocking capability of the transistor device is higher in the termination structure in the edge region 105 than in the inner region 104. Thus, an avalanche breakdown, at first, occurs in the inner region 104 which usually has a much larger area than the edge region 105. Ionizing the second type dopant atoms in the compensation region 40 when the transistor device switches off is equivalent to charging the compensation region 40. The compensation region 40 is discharged when the transistor device switches on again, wherein such discharging is obtained by inevitable leakage currents.

FIG. 8 shows one example of how the body regions 12 and the source regions 13 of the individual transistor cells 10 can be connected to the source node S. In this example, a source electrode 41, which is connected to the source node S forms the source node S, is arranged on top of the first surface 101, and has a plug section that extends through the source region 13 into the body region 12 so that both the source region 13 and the body region 12 are electrically connected to the source electrode 41. Optionally, the body region 12 includes a contact region 16 of the same doping type as the body region 12, but more highly doped. This contact region 16 forms an ohmic contact between the body region 12 and the source electrode 41.

According to another example shown in FIG. 9, the source electrode 41 is only arranged on top of the first surface 101 of the semiconductor body. In this example, a section of the body region 12 extends to the first surface 101 so that both the body region 12 and the source region 13 are electrically connected to the source electrode 41 in the region of the first surface 101. Optionally, the body region 12, in the section extending to the first surface 101, has a contact region of the same doping type as the body region 12 but more highly doped than other sections of the body region 12. This contact region 16 provides for an ohmic contact between the source electrode 41 and the body region 12.

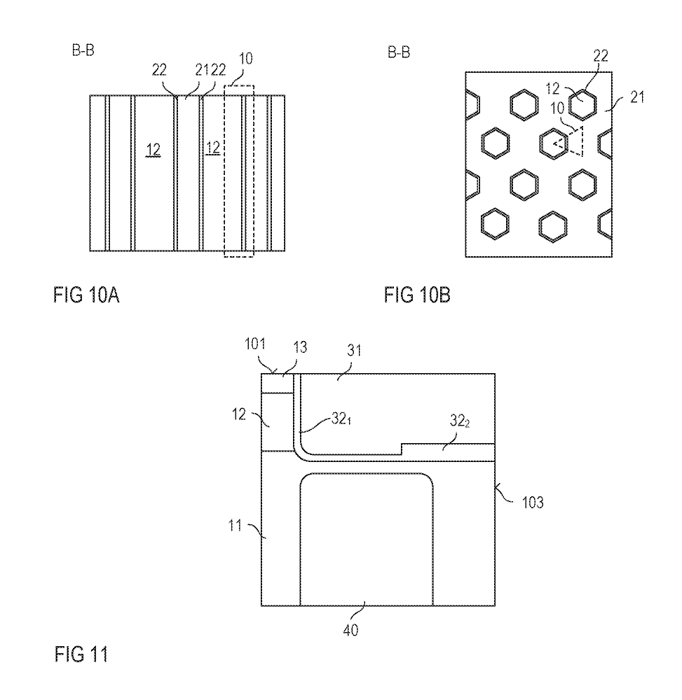

FIGS. 10A and 10B show different examples of how the transistor cells 10 may be implemented, that is, how the gate electrodes 21 and the body regions 12 may be implemented. It should be noted, that FIGS. 8A and 8B show two of many possible examples so that the transistor device is not restricted to be implemented with one of these transistor cells shown in FIGS. 8A and 8B.

In the example shown in FIG. 10A, the transistor cells 10 are elongated transistor cells. In this example, the gate electrodes 21 are elongated in a lateral direction of the semiconductor body 100. Consequently, the body regions 12 are elongated in this lateral direction of the semiconductor body 100, wherein each body region is arranged between two gate electrodes 21. In this example, two neighboring transistor cells share one gate electrode, and two neighboring transistor cells share one body region 12. That is, the gate electrodes of two neighboring transistor cells are formed by one electrode, and the body regions of two neighboring transistor cells are formed by one doped semiconductor region.

In the example shown in FIG. 10B, there is only one electrode that forms the gate electrodes 21 of the individual transistor cells. This electrode has a grid shape wherein, just for the purpose of illustration, openings of the grid have a hexagonal form in the example shown in FIG. 10B. However, other types of openings such as rectangular, circular or any other type of polygonal openings may be implemented as well.

FIG. 11 shows one example of the field electrode dielectric 32. In this example, the field electrode dielectric 32 has a first section 32₁ with a first thickness and a second section 32₂ with a second thickness. The first section adjoins the source region 13 and the body region 12 of the outermost transistor cell. The “outermost transistor cell” is the transistor cell arranged next to the field electrode 31. The second section 32₂ of the field electrode dielectric is thicker than the first section 32₁ and adjoins the drift region 11. According to one example, a thickness of the first section 32₁ is between 0.8 times and 2 times the thickness of the gate dielectric 22. According to one example, the thickness of the gate dielectric 22 is selected from between 20 nanometers (nm) and 50 nanometers, in particular between 30 nanometers and 40 nanometers. According to one example, a thickness of the second section 32₂ is at least 5 times or at least 10 times the thickness of the first section 32₁.

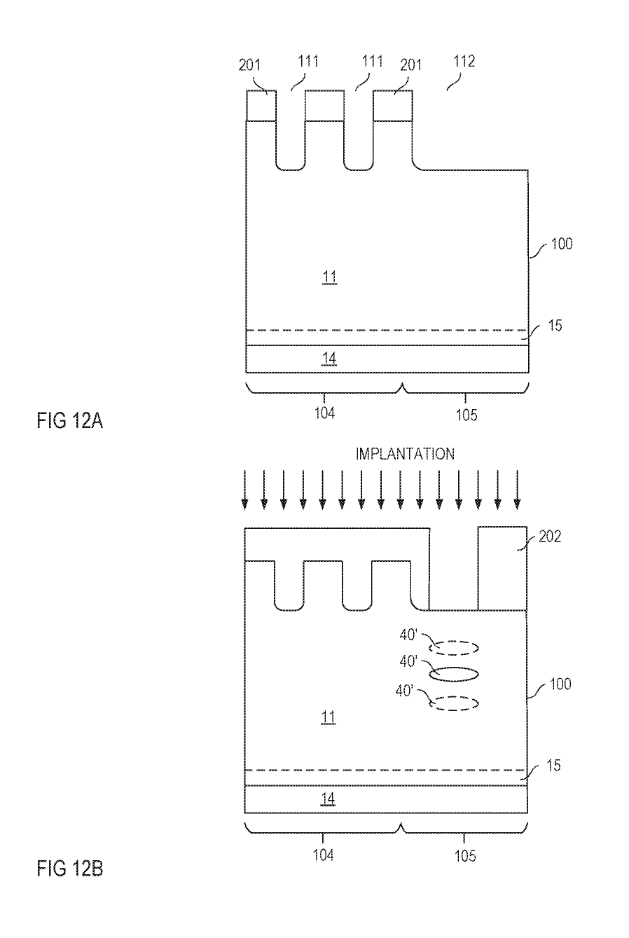

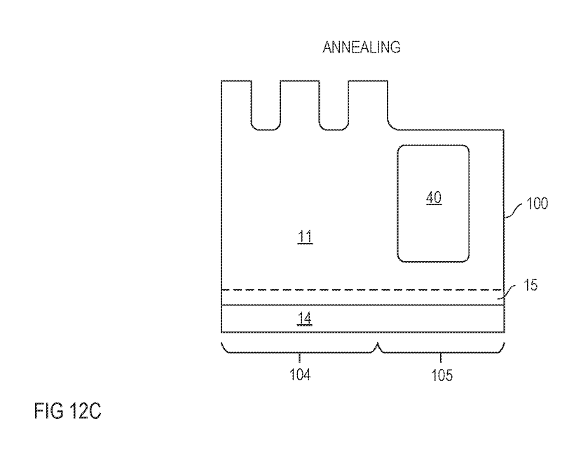

FIGS. 12A to 12C illustrate one example of a method for forming the floating compensation region 40. Each of the FIGS. 12A to 12C shows a vertical cross sectional view of the semiconductor body 100 in the edge region 105 during or after individual processing steps. Referring to FIG. 12A, the method includes forming the recess 112 in the edge region 105. Forming the recess 112 may include an etching process using an etch mask 201. According to one example, the recess 112 and trenches 111 which, in the finished transistor device, accommodate that gate electrodes 21 and the gate dielectrics 22 are formed by the same etching process.

Referring to FIG. 12B, the method further includes implanting dopant atoms of the second doping type into the drift region 11 in a region below the recess 112. This implantation process uses an implantation mask 202, wherein the implantation mask 202 is formed such that it only uncovers those regions at a bottom of the recess 112 into which the dopant atoms are to be implanted.

The implantation process may include one implantation at one implantation energy or may include two or more implantations with different implantation energies. In FIG. 12B, 40′ denotes those regions into which dopant atoms are implanted. There is one region 40′ if there is only one implantation and there are two or more of these regions 40′ when there are two or more implantation processes at different energies.

Referring to FIG. 12C, forming the compensation region 40 further includes an annealing process. In this annealing process, the implanted dopant atoms diffuse in the drift region 11 and are activated. This annealing process can be a dedicated annealing process only used to diffuse and activate the dopant atoms of the compensation region 40. According to another example, this annealing takes place after dopant atoms for forming the source and body regions have been implanted so that in the annealing process not only the dopant atoms of the compensation region 40 are activated, but also the dopant atoms that form the source and body regions 13, 12 of the transistor device.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention he limited only by the claims and the equivalents thereof.

What is claimed is:

1. A transistor device, comprising:
a semiconductor body with a first surface, an inner region, and an edge region;
a drift region of a first doping type in the inner region and the edge region;
a plurality of transistor cells in the inner region; and
a termination structure in the edge region, the termination structure comprising a recess extending from the first surface in the edge region into the semiconductor body, and a floating compensation region comprising dopant atoms of a second doping type complementary to the first doping type in the drift region adjacent the recess.

2. The transistor device of claim 1, further comprising:
a field electrode arranged in the recess and dielectrically insulated from the semiconductor body by a field electrode dielectric.

3. The transistor device of claim 1, further comprising:
a dielectric filling the recess.

4. The transistor device of claim 1, wherein the drift region has a first doping dose of first type doping atoms and the floating compensation region has a second doping dose of second type doping atoms, and wherein a dose ratio between the second doping dose and the first doping dose is between 0.5 and 4.

5. The transistor device of claim 4, wherein the dose ratio is between 0.7 and 2.5.

6. The transistor device of claim 4, wherein the second doping dose is between 1E11 cm⁻² and 1E13 cm⁻².

7. The transistor device of claim 1, wherein the drift region, in a vertical direction of the semiconductor body adjacent the recess, has a first length, wherein the floating compensation region, in the vertical direction of the semiconductor body, has a second length, and wherein a length ratio between the second length and the first length is between 0.4 and 1.

8. The transistor device of claim 7, wherein the length ratio is between 0.5 and 0.9.

9. The transistor device of claim 7, wherein the first length is between 2 micrometers and 10 micrometers.

10. The transistor device of claim 1, wherein each of the plurality of transistor cells comprises:
a source region;
a body region arranged between the source region and the drift region; and
a gate electrode adjacent the body region and dielectrically insulated from the body region by a gate dielectric.

11. The transistor device of claim 10, wherein the gate electrode is arranged in a trench extending from the first surface into the semiconductor body.

12. The transistor device of claim 11, wherein the recess has a first depth in a vertical direction of the semiconductor body, wherein the trench has a second depth in the vertical direction of the semiconductor body, and wherein a depth ratio between the second depth and the first depth is between 0.9 and 1.1.

13. The transistor device of claim 10, further comprising:
a field electrode arranged in the recess and dielectrically insulated from the semiconductor body by a field electrode dielectric,
wherein the gate electrode of each of the plurality of transistor cells is connected to a gate node,
wherein the source region of each of the plurality of transistor cells is connected to a source node,
wherein the field electrode is connected to one of the gate node and the source node.

14. The transistor device of claim 1, wherein the semiconductor body comprises an edge surface that terminates the semiconductor body in lateral directions, and wherein the recess extends to the edge surface.

15. The transistor device of claim 1, further comprising:
a drain region adjacent the drift region.

16. A method, comprising:
forming a drift of a first doping type in an inner region and an edge region of a semiconductor;
forming a plurality of transistor cells in the inner region; and
forming a termination structure in the edge region, wherein forming the termination structure comprises:
forming a recess extending, in the edge region, from the first surface in the edge region into the semiconductor body; and
forming a floating compensation region comprising dopant atoms of a second doping type complementary to the first doping type in the drift region adjacent the recess.

17. The method of claim 16, wherein forming the floating compensation region comprises at least one implantation process.

18. The method of claim 17, wherein the at least one implantation process comprises two or more implantation processes each having an implantation energy, and wherein implantation energies of the two or more implantation processes are mutually different.

19. The method of claim 16, wherein forming the drift region comprises forming the drift region to have a first doping dose, wherein forming the floating compensation region comprises forming the floating compensation region to have a second doping dose, and wherein a dose ratio between the second doping dose and the first doping dose is between 0.5 and 3.

20. The method of claim 19, wherein the second doping dose is between 1E11 cm⁻² and 1E13 cm⁻².

21. The method of claim 16, wherein forming the drift region comprises forming the drift region to have a first length in a vertical direction of the semiconductor body adjacent the recess, wherein forming the floating compensation region comprises forming the floating compensation region to have a second length in the vertical direction of the semiconductor body, and wherein a length ratio between the second length and the first length is between 0.4 and 1.

22. The method of claim 21, wherein the first length is between 2 micrometers and 10 micrometers.

23. The method of claim 16, wherein forming each of the plurality of transistor cells comprises:
forming a source region;
forming a body region between the source region and the drift region; and
forming a gate electrode adjacent the body region and dielectrically insulated from the body region by a gate dielectric.

24. The method of claim 23, wherein forming the gate electrode comprises forming the gate electrode in a trench extending from the first surface into the semiconductor body.

25. The method of claim 24, wherein forming the recess comprises forming the recess to have a first depth in a vertical direction of the semiconductor body, wherein forming the trench comprises forming the trench to have a second depth in the vertical direction of the semiconductor body, and wherein a depth ratio between the second depth and the first depth is between 0.9 and 1.1.

26. The method of claim 16, wherein forming the termination structure further comprises:
in the recess, forming a field electrode dielectrically insulated from the semiconductor body by a field electrode dielectric.
